(19) United States
(12) Patent Application Publication
(10) Pub. No.: US 2023/0320185 A1
(43) Pub. Date: Oct. 5, 2023

(54) MANUFACTURING METHOD OF DISPLAY DEVICE

(71) Applicant: Japan Display Inc., Tokyo (JP)

(72) Inventors: Hiraaki KOKAME, Tokyo (JP); Toshifumi MIMURA, Tokyo (JP)

(73) Assignee: Japan Display Inc., Tokyo (JP)

(21) Appl. No.: 18/191,001

(22) Filed: Mar. 28, 2023

(30) Foreign Application Priority Data
Mar. 29, 2022 (JP) 2022-053327

(51) Int. Cl. H10K 71/20

(52) U.S. Cl. CPC H10K 71/231; H10K 59/871

(57) ABSTRACT

According to one embodiment, a manufacturing method of a display device includes forming a first display element on a substrate, the first display element including a first lower electrode, a first upper electrode and a first organic layer located between the first lower electrode and the first upper electrode, forming a first sealing layer which covers the first display element, forming a first resist on the first sealing layer, and removing, of the first sealing layer and the first display element, a portion exposed from the first resist by a first patterning process including washing of the substrate with a cleaning liquid containing water.

### CROSS-REFERENCE TO RELATED APPLICATIONS

This application is based upon and claims the benefit of priority from Japanese Patent Application No. 2022-053327, filed Mar. 29, 2022, the entire contents of which are incorporated herein by reference.

### FIELD

Embodiments described herein relate generally to a manufacturing method of a display device.

### BACKGROUND

Recently, display devices to which an organic light emitting diode (OLED) is applied as a display element have been put into practical use. This display element comprises a lower electrode, an organic layer which covers the lower electrode, and an upper electrode which covers the organic layer.

When such a display device is manufactured, a technique which prevents the reduction in reliability is required.

### BRIEF DESCRIPTION OF THE DRAWINGS

FIG. 1 is a diagram showing a configuration example of a display device according to an embodiment.

FIG. 2 is a diagram showing an example of the layout of subpixels.

FIG. 3 is a schematic cross-sectional view of the display device along the III-III line of FIG. 2.

FIG. 4 is a schematic cross-sectional view in which a partition provided between a first subpixel and a second subpixel and its vicinity are enlarged.

FIG. 5 is a flowchart showing an example of a manufacturing method of the display device.

FIG. 6 is a flowchart showing the detail of the patterning processes in FIG. 5.

FIG. 7 is a schematic cross-sectional view showing part of the manufacturing process of the display device.

FIG. 8 is a schematic cross-sectional view showing a manufacturing process following FIG. 7.

FIG. 9 is a schematic cross-sectional view showing a manufacturing process following FIG. 8.

FIG. 10 is a schematic cross-sectional view showing a manufacturing process following FIG. 9.

FIG. 11 is a schematic cross-sectional view showing a manufacturing process following FIG. 10.

FIG. 12 is a schematic cross-sectional view showing a manufacturing process following FIG. 11.

FIG. 13 is a schematic cross-sectional view showing a manufacturing process following FIG. 12.

FIG. 14 is a schematic cross-sectional view showing a manufacturing process following FIG. 13.

FIG. 15 is a schematic cross-sectional view showing a manufacturing process following FIG. 14.

FIG. 16 is a schematic cross-sectional view showing a manufacturing process following FIG. 15.

FIG. 17 is a schematic cross-sectional view showing a manufacturing process following FIG. 16.

FIG. 18 is a schematic cross-sectional view showing a manufacturing process following FIG. 17.

FIG. 19 is a schematic cross-sectional view showing a manufacturing process following FIG. 18.

FIG. 20 is a schematic cross-sectional view showing a manufacturing process following FIG. 19.

FIG. 21 is a schematic cross-sectional view showing a manufacturing process following FIG. 20.

FIG. 22 is a flowchart showing a patterning process according to a first modified example.

FIG. 23 is a flowchart showing a patterning process according to a second modified example.

### DETAILED DESCRIPTION

In general, according to one embodiment, a manufacturing method of a display device includes forming a first display element on a substrate, the first display element including a first lower electrode, a first upper electrode and a first organic layer located between the first lower electrode and the first upper electrode, forming a first sealing layer which covers the first display element, forming a first resist on the first sealing layer, and removing, of the first sealing layer and the first display element, a portion exposed from the first resist by a first patterning process including washing of the substrate with a cleaning liquid containing water.

This manufacturing method can improve the reliability of a display device.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction. A direction parallel to the Y-axis is referred to as a second direction. A direction parallel to the Z-axis is referred to as a third direction. A plan view is defined as appearance when various types of elements are viewed parallel to the third direction Z.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

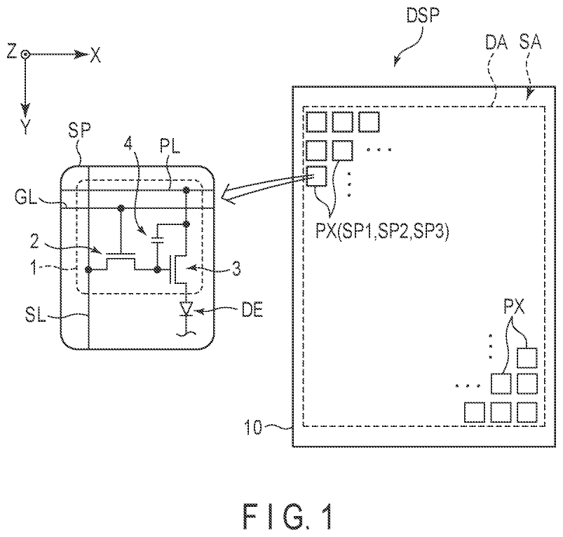

FIG. 1 is a diagram showing a configuration example of a display device DSP according to an embodiment. The display device DSP comprises a display area DA which displays an image and a surrounding area SA around the display area DA on an insulating substrate 10. The substrate 10 may be glass or a resinous film having flexibility.

In the present embodiment, the substrate 10 is rectangular as seen in plan view. It should be noted that the shape of the substrate 10 in plan view is not limited to a rectangular shape and may be another shape such as a square shape, a circular shape or an elliptic shape.

The display area DA comprises a plurality of pixels PX arrayed in matrix in a first direction X and a second direction Y. Each pixel PX includes a plurality of subpixels SP. For example, each pixel PX includes a blue first subpixel SP1, a green second subpixel SP2 and a red third subpixel SP3. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. The pixel switch 2 and the drive transistor 3 are, for example, switching elements consisting of thin-film transistors.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the display element DE. The display element DE is an organic light emitting diode (OLED) as a light emitting element.

It should be noted that the configuration of the pixel circuit 1 is not limited to the example shown in the figure. For example, the pixel circuit 1 may comprise more thin-film transistors and capacitors.

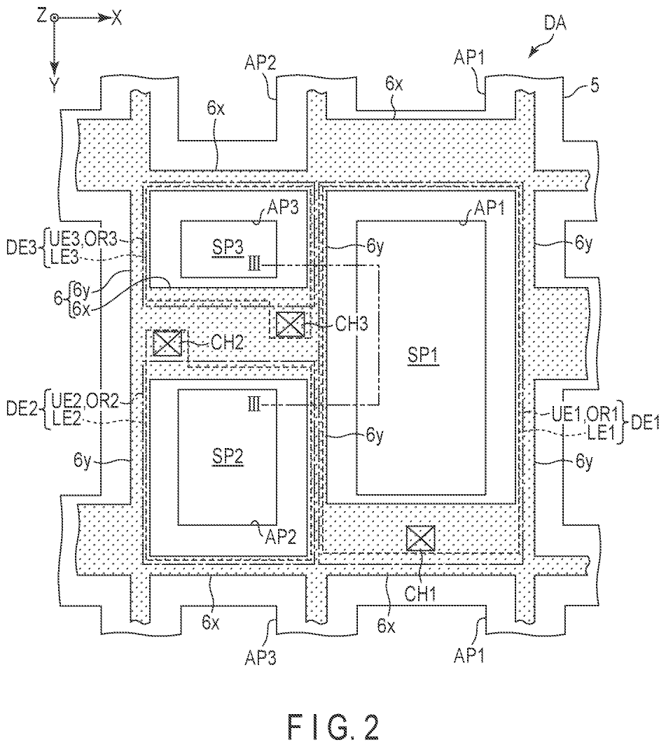

FIG. 2 is a diagram showing an example of the layout of subpixels SP1, SP2 and SP3. In the example of FIG. 2, the second subpixel SP2 and the first subpixel SP1 are arranged in the first direction X. The third subpixel SP3 and the first subpixel SP1 are also arranged in the first direction X. Further, the third subpixel SP3 and the second subpixel SP2 are arranged in the second direction Y.

When subpixels SP1, SP2 and SP3 are provided in line with this layout, in the display area DA, a column in which a plurality of first subpixels SP1 are repeatedly provided in the second direction Y and a column in which subpixels SP2 and SP3 are alternately provided in the second direction Y are formed. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

A rib 5 and a partition 6 are provided in the display area DA. The rib 5 comprises a first pixel aperture AP1 in the first subpixel SP1, comprises a second pixel aperture AP2 in the second subpixel SP2 and comprises a third pixel aperture AP3 in the third subpixel SP3. In the example of FIG. 2, the second pixel aperture AP2 is larger than the third pixel aperture AP3, and the first pixel aperture AP1 is larger than the second pixel aperture AP2.

The partition 6 is provided in the boundary between adjacent subpixels SP and overlaps the rib 5 as seen in plan view. The partition 6 comprises a plurality of first partitions 6x extending in the first direction X and a plurality of second partitions 6y extending in the second direction Y. The first partitions 6x are provided between two first pixel apertures AP1 which are adjacent to each other in the second direction Y and between the pixel apertures AP2 and AP3 which are adjacent to each other in the second diction Y. Each second partition 6y is provided between the pixel apertures AP1 and AP2 which are adjacent to each other in the first direction X and between the pixel apertures AP1 and AP3 which are adjacent to each other in the first direction X.

In the example of FIG. 2, the first partitions 6x and the second partitions 6y are connected to each other. In this configuration, the partition 6 has a grating shape surrounding the pixel apertures AP1, AP2 and AP3 as a whole. In other words, the partition 6 comprises apertures in subpixels SP1, SP2 and SP3 in a manner similar to that of the rib 5.

The first subpixel SP1 comprises a first lower electrode LE1, a first upper electrode UE1 and a first organic layer OR1 overlapping the first pixel aperture AP1. The second subpixel SP2 comprises a second lower electrode LE2, a second upper electrode UE2 and a second organic layer OR2 overlapping the second pixel aperture AP2. The third subpixel SP3 comprises a third lower electrode LE3, a third upper electrode UE3 and a third organic layer OR3 overlapping the third pixel aperture AP3.

The first lower electrode LE1, the first upper electrode UE1 and the first organic layer OR1 constitute the first display element DE1 of the first subpixel SP1. The second lower electrode LE2, the second upper electrode UE2 and the second organic layer OR2 constitute the second display element DE2 of the second subpixel SP2. The third lower electrode LE3, the third upper electrode UE3 and the third organic layer OR3 constitute the third display element DE3 of the third subpixel SP3. Each of the display elements DE1, DE2 and DE3 may include a cap layer as described later.

For example, the first display element DE1 emits light in a blue wavelength range. The second display element DE2 emits light in a green wavelength range. The third display element DE3 emits light in a red wavelength range.

The first lower electrode LE1 is connected to the pixel circuit 1 (see FIG. 1) of the first subpixel SP1 through a first contact hole CH1. The second lower electrode LE2 is connected to the pixel circuit 1 of the second subpixel SP2 through a second contact hole CH2. The third lower electrode LE3 is connected to the pixel circuit 1 of the third subpixel SP3 through a third contact hole CH3.

In the example of FIG. 2, the first contact hole CH1 entirely overlaps the first partition 6x between two first pixel apertures AP1 which are adjacent to each other in the second direction Y. The contact holes CH2 and CH3 entirely overlap the first partition 6x between the pixel apertures AP2 and AP3 which are adjacent to each other in the second direction Y. As another example, at least part of the contact hole CH1, CH2 or CH3 may not overlap the first partition 6x.

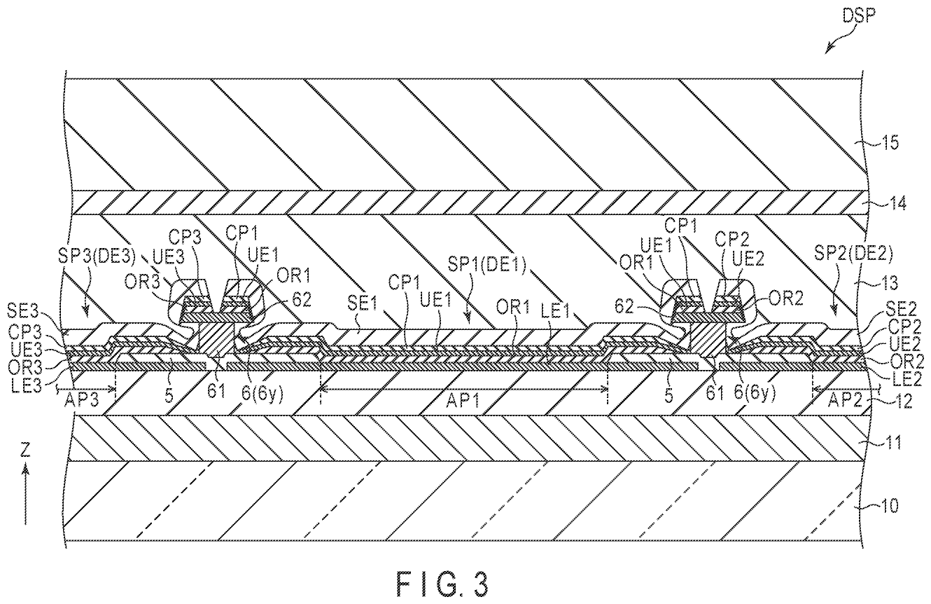

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuit 1, scanning line GL, signal line SL and power line PL shown in FIG. 1.

The circuit layer 11 is covered with an organic insulating layer 12. The organic insulating layer 12 functions as a planarization film which planarizes the irregularities formed by the circuit layer 11. Although not shown in the section of FIG. 3, all of the contact holes CH1, CH2 and CH3 described above are provided in the organic insulating layer 12.

The lower electrodes LE1, LE2 and LE3 are provided on the organic insulating layer 12. The rib 5 is provided on the organic insulating layer 12 and the lower electrodes LE1, LE2 and LE3. The end portions of the lower electrodes LE1, LE2 and LE3 are covered with the rib 5.

The partition 6 includes a conductive lower portion 61 provided on the rib 5 and an upper portion 62 provided on the lower portion 61. The upper portion 62 has a width greater than that of the lower portion 61. By this configuration, in FIG. 3, the both end portions of the upper portion 62 protrude relative to the side surfaces of the lower portion 61. This shape of the partition 6 may be called an overhang shape.

The first organic layer OR1 covers the first lower electrode LE1 through the first pixel aperture AP1. The first upper electrode UE1 covers the first organic layer OR1 and faces the first lower electrode LE1. The second organic layer OR2 covers the second lower electrode LE2 through the second pixel aperture AP2. The second upper electrode UE2 covers the second organic layer OR2 and faces the second lower electrode LE2. The third organic layer OR3 covers the third lower electrode LE3 through the third pixel aperture AP3. The third upper electrode UE3 covers the third organic layer OR3 and faces the third lower electrode LE3.

In the example of FIG. 3, a first cap layer CP1 is provided on the first upper electrode UE1. A second cap layer CP2 is provided on the second upper electrode UE2. A third cap layer CP3 is provided on the third upper electrode UE3. The cap layers CP1, CP2 and CP3 adjust the optical property of the light emitted from the organic layers OR1, OR2 and OR3, respectively.

The first organic layer OR1, the first upper electrode UE1 and the first cap layer CP1 are partly located on the upper portion 62. These portions are spaced apart from the other portions of the first organic layer OR1, the first upper electrode UE1 and the first cap layer CP1. Similarly, the second organic layer OR2, the second upper electrode UE2 and the second cap layer CP2 are partly located on the second portion 62, and these portions are spaced apart from the other portions of the second organic layer OR2, the second upper electrode UE2 and the second cap layer CP2. Further, the third organic layer OR3, the third upper electrode UE3 and the third cap layer CP3 are partly located on the upper portion 62, and these portions are spaced apart from the other portions of the third organic layer OR3, the third upper electrode UE3 and the third cap layer CP3.

A first sealing layer SE1 is provided in the first subpixel SP1. A second sealing layer SE2 is provided in the second subpixel SP2. A third sealing layer SE3 is provided in the third subpixel SP3. The first sealing layer SE1 continuously covers the first cap layer CP1 and the partition 6 around the first subpixel SP1. The second sealing layer SE2 continuously covers the second cap layer CP2 and the partition 6 around the second subpixel SP2. The third sealing layer SE3 continuously covers the third cap layer CP3 and the partition 6 around the third subpixel SP3.

The sealing layers SE1, SE2 and SE3 are covered with a resinous layer 13. The resinous layer 13 is covered with a sealing layer 14. Further, the sealing layer 14 is covered with a resinous layer 15.

The organic insulating layer 12 and the resinous layers 13 and 15 are formed of an organic material. The rib 5 and the sealing layers 14, SE1, SE2 and SE3 are formed of, for example, an inorganic material such as silicon nitride (SiNx). Each of the rib 5 and the sealing layers 14, SE1, SE2 and SE3 may be formed as a single-layer body of one of silicon oxide (SiOx), silicon oxynitride (SiON) and aluminum oxide (Al₂O₃). Each of the rib 5 and the sealing layers 14, SE1, SE2 and SE3 may be formed as a stacked layer body of a combination consisting of at least two of a silicon nitride layer, a silicon oxide layer, a silicon oxynitride layer and an aluminum oxide layer.

Each of the lower electrodes LE1, LE2 and LE3 comprises an intermediate layer formed of, for example, silver (Ag), and a pair of conductive oxide layers covering the upper and lower surfaces of the intermediate layer. Each conductive oxide layer may be formed of, for example, a transparent conductive oxide such as indium tin oxide (ITO), indium zinc oxide (IZO) or indium gallium zinc oxide (IGZO). The upper electrodes UE1, UE2 and UE3 are formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

The organic layers OR1, OR2 and OR3 include a pair of functional layers and a light emitting layer provided between these functional layers. For example, the organic layers OR1, OR2 and OR3 comprise a structure in which a hole injection layer, a hole transport layer, an electron blocking layer, a light emitting layer, a hole blocking layer, an electron transport layer and an electron injection layer are stacked in order.

The cap layers CP1, CP2 and CP3 are formed of, for example, a multilayer body of a plurality of transparent thin films. As the thin films, the multilayer body may include a thin film formed of an inorganic material and a thin film formed of an organic material. These thin films have refractive indices different from each other. The materials of the thin films constituting the multilayer body are different from the materials of the upper electrodes UE1, UE2 and UE3 and are also different from the materials of the sealing layers SE1, SE2 and SE3. It should be noted that the cap layers CP1, CP2 and CP3 may be omitted.

Common voltage is applied to the partition 6. This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits 1 provided in subpixels SP1, SP2 and SP3, respectively.

When a potential difference is formed between the first lower electrode LE1 and the first upper electrode UE1, the light emitting layer of the first organic layer OR1 emits light in a blue wavelength range. When a potential difference is formed between the second lower electrode LE2 and the second upper electrode UE2, the light emitting layer of the second organic layer OR2 emits light in a green wavelength range. When a potential difference is formed between the third lower electrode LE3 and the third upper electrode UE3, the light emitting layer of the third organic layer OR3 emits light in a red wavelength range.

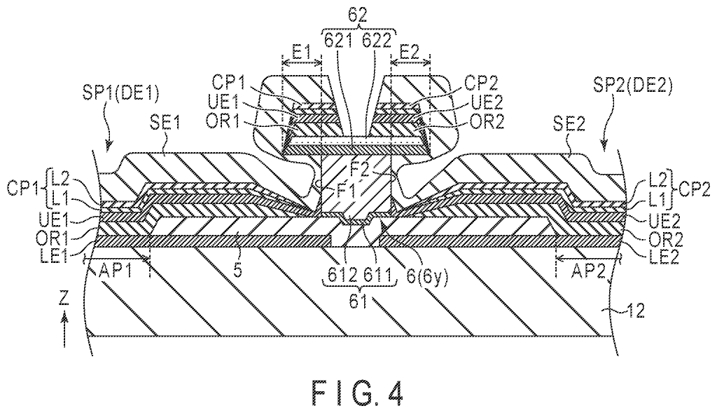

FIG. 4 is a schematic cross-sectional view in which the partition 6 provided between subpixels SP1 and SP2 and its vicinity are enlarged. In this figure, the substrate 10, the circuit layer 11, the resinous layer 13, the sealing layer 14 and the resinous layer 15 are omitted.

The lower portion 61 of the partition 6 comprises a first side surface F1 on the first subpixel SP1 side (the first display element DE1 side) and a second side surface F2 on the second subpixel SP2 side (the second display element DE2 side). The upper portion 62 of the partition 6 comprises a first end portion E1 which protrudes from the first side surface F1 and a second end portion E2 which protrudes from the second side surface F2. The first upper electrode UE1 is in contact with the first side surface F1. The second upper electrode UE2 is in contact with the second side surface F2.

In the example of FIG. 4, the lower portion 61 comprises a first metal layer 611 provided on the rib 5, and a second metal layer 612 provided on the first metal layer 611. The second metal layer 612 is formed so as to be thicker than the first metal layer 611.

In the example of FIG. 4, the upper portion 62 comprises a first thin film 621 provided on the second metal layer 612, and a second thin film 622 provided on the first thin film 621.

The first metal layer 611 is formed of, for example, molybdenum (Mo). The second metal layer 612 is formed of, for example, aluminum (Al). The second metal layer 612 may be formed of aluminum alloy or may comprise a multilayer structure of aluminum and aluminum alloy.

The first thin film 621 is formed of, for example, titanium (Ti). The second thin film 622 is formed of, for example, a transparent conductive oxide such as ITO, IZO or IGZO.

It should be noted that at least one of the lower portion 61 and the upper portion 62 may comprise a single-layer structure. The lower portion 61 comprising a single-layer structure may be formed of, for example, aluminum or aluminum alloy. The upper portion 62 comprising a single-layer structure may be formed of, for example, titanium or silicon oxide.

In the example of FIG. 4, the first cap layer CP1 comprises a first layer L1 which covers the first upper electrode UE1 and a second layer L2 which covers the first layer L1. Similarly, each of the second cap layer CP2 and the third cap layer CP3 comprises a first layer L1 and a second layer L2. For example, the first layer L1 is formed of an organic material, and the second layer L2 is formed of an inorganic material such as lithium fluoride (LiF).

In the example of FIG. 3 and FIG. 4, the first organic layer OR1, the first upper electrode UE1 and the first cap layer CP1 on the upper portion 62 are spaced apart from the second organic layer OR2, the second upper electrode UE2 and the second cap layer CP2 on the upper portion 62.

The first sealing layer SE1 continuously covers the first display element DE1, the first side surface F1 and the first end portion E1. The second sealing layer SE2 continuously covers the second display element DE2, the second side surface F2 and the second end portion E2. The end portions of the first and second sealing layers SE1 and SE2 are located above the upper portion 62 and are spaced apart from each other.

The configuration of the partition 6 between subpixels SP1 and SP3 and its vicinity and the configuration of the partition 6 between subpixels SP2 and SP3 and its vicinity are similar to the configuration of the partition 6 between subpixels SP1 and SP2 and its vicinity in FIG. 4.

Now, this specification explains a manufacturing method of the display device DSP.

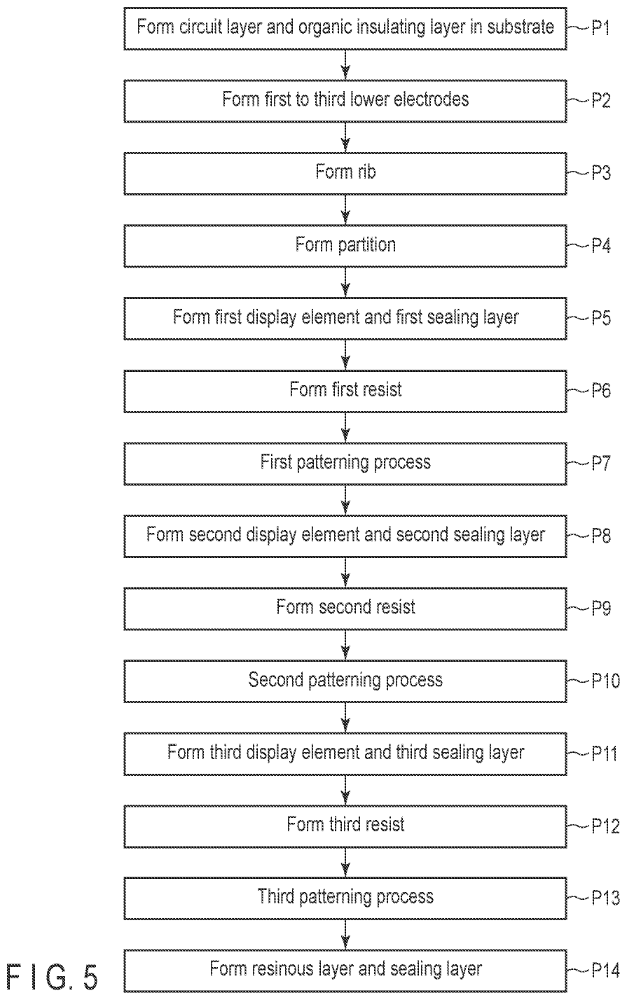

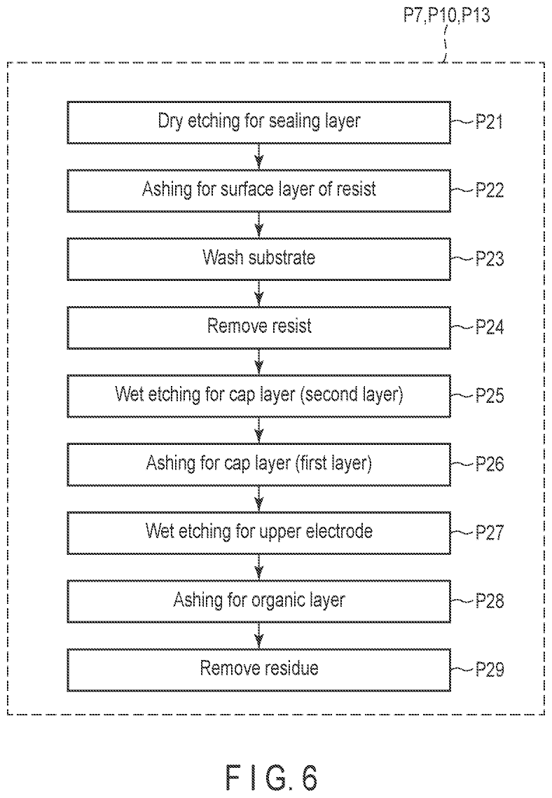

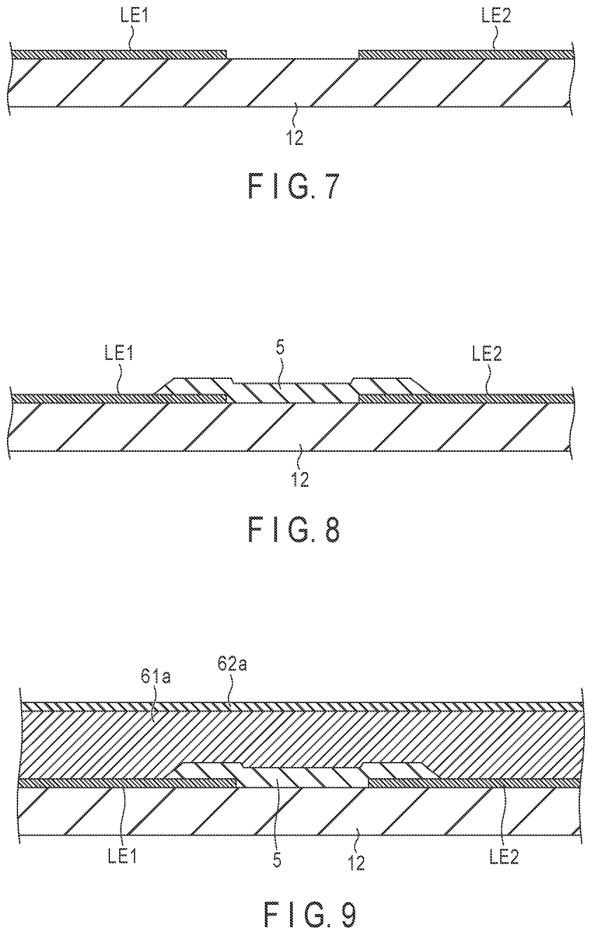

FIG. 5 is a flowchart showing an example of a manufacturing method of the display device DSP. FIG. 6 is a flowchart showing the detail of the patterning processes (processes P7, P10 and P13) in FIG. 5. Each of FIG. 7 to FIG. 21 is a schematic cross-sectional view showing part of the manufacturing process of the display device DSP. In FIG. 7 to FIG. 21, the substrate 10 and the circuit layer 11 are omitted.

To manufacture the display device DSP, first, the circuit layer 11 and the organic insulating layer 12 are formed on the substrate 10 (process P1 in FIG. 5).

After process P1, as shown in FIG. 7, the lower electrodes LE1, LE2 and LE3 are formed on the organic insulating layer 12 (process P2 in FIG. 5).

After process P2, as shown in FIG. 8, the rib 5 which covers the end portions of the lower electrodes LE1, LE2 and LE3 is formed (process P3 in FIG. 5). It should be noted that the pixel apertures AP1, AP2 and AP3 may be formed in process P3 or may be formed after the formation of the partition 6.

After process P3, the partition 6 is formed (process P4 in FIG. 5). Specifically, first, as shown in FIG. 9, a metal layer 61a which is the base of the lower portion 61 is formed on the rib 5, and a thin film 62a which is the base of the upper portion 62 is formed on the metal layer 61a.

When the lower portion 61 includes the first metal layer 611 and the second metal layer 612 as shown in FIG. 4, the metal layer 61a includes two layers formed of the materials of the metal layers 611 and 612. When the upper portion 62 includes the first thin film 621 and the second thin film 622 as shown in FIG. 4, the thin film 62a includes two layers formed of the materials of the thin films 621 and 622.

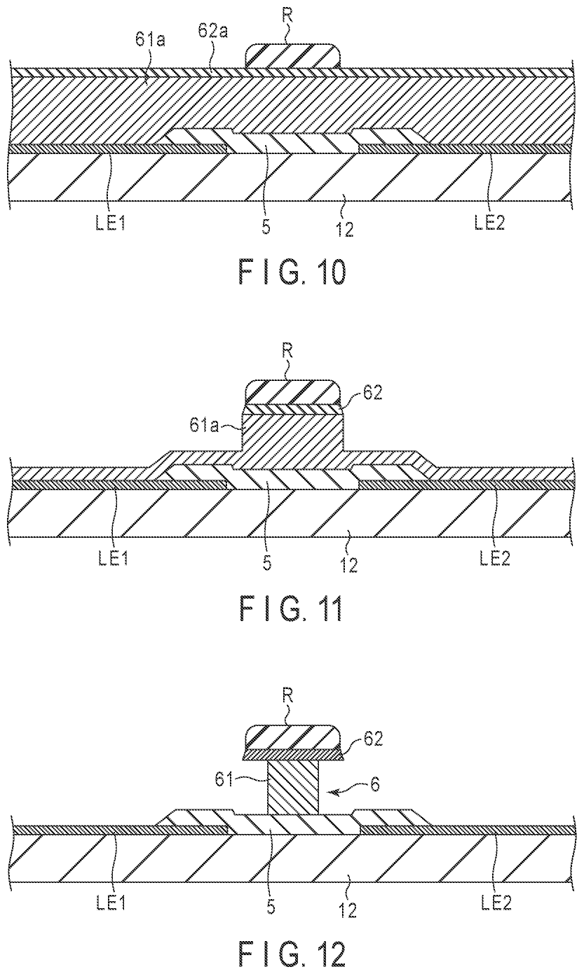

Subsequently, as shown in FIG. 10, a resist R corresponding to the shape of the partition 6 is formed on the thin film 62a. Further, of the thin film 62a and the metal layer 61a, the portions exposed from the resist R are removed by etching using the resist R as a mask. By this process, as shown in FIG. 11, the upper portion 62 is formed. In the example of FIG. 11, of the metal layer 61a, the portion exposed from the resist R partly remains. For example, the etching applied to, of the thin film 62a, the layer which is the base of the second film 622 may be wet etching, and the etching applied to, of the thin film 62a, the layer which is the base of the first thin film 621 and the metal layer 61a may be anisotropic dry etching.

Subsequently, isotropic wet etching is applied to the metal layer 61a. For example, for the wet etching, an etchant containing phosphoric acid, nitric acid and acetic acid is used. By this wet etching, of the metal layer 61a, the portion exposed from the resist R is removed. As shown in FIG. 12, the lower portion 61 is formed. In this wet etching, the side surfaces of the lower portion 61 also corrode. Thus, the width of the lower portion 61 is made less than that of the upper portion 62. In this way, the partition 6 having an overhang shape is obtained. After the wet etching, the resist R is removed.

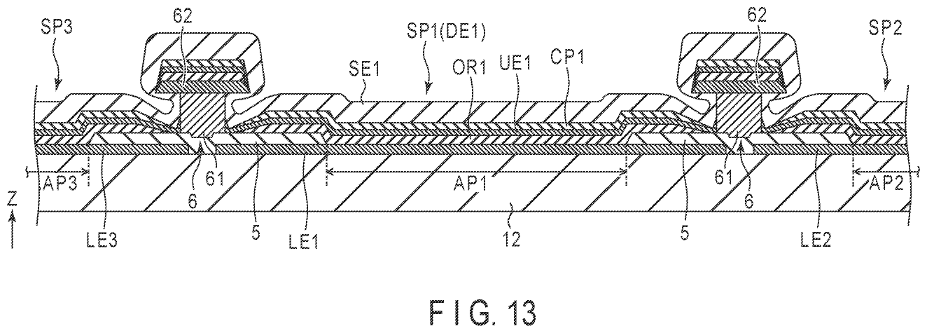

After process P4, the first display element DE1 and the first sealing layer SE1 are formed (process P5 in FIG. 5). Specifically, as shown in FIG. 13, the first organic layer OR1 which is in contact with the first lower electrode LE1 through the first pixel aperture AP1, the first upper electrode UE1 which covers the first organic layer OR1 and the first cap layer CP1 which covers the first upper electrode UE1 are formed in order by vapor deposition. Further, the first sealing layer SE1 which continuously covers the first cap layer CP1 and the partition 6 is formed by chemical vapor deposition (CVD).

These first organic layer OR1, first upper electrode UE1, first cap layer CP1 and first sealing layer SE1 are formed in at least the entire display area DA and are provided in the second subpixel SP2 and the third subpixel SP3 as well as the first subpixel SP1. The first organic layer OR1, the first upper electrode UE1 and the first cap layer CP1 are divided by the partition 6 having an overhang shape.

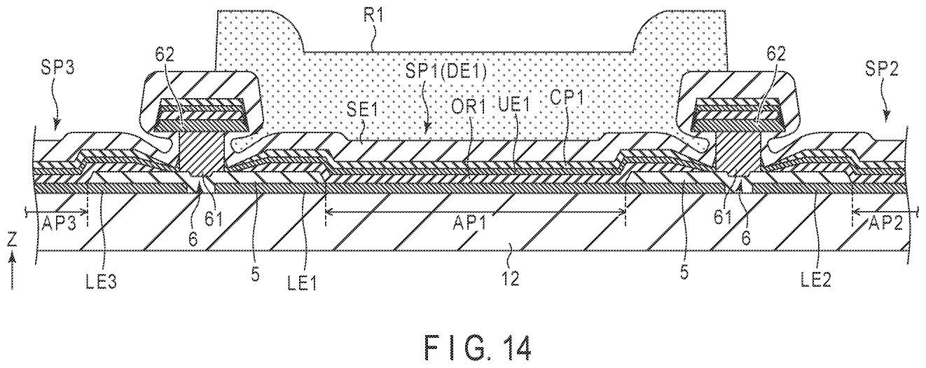

After process P5, as shown in FIG. 14, a first resist R1 is formed on the first sealing layer SE1 (process P6 in FIG. 5). The first resist R1 covers the first subpixel SP1 and part of the partition 6 around the first subpixel SP1.

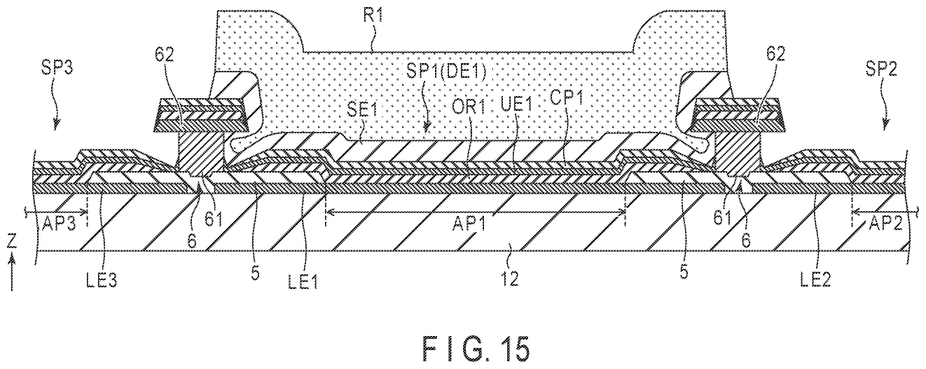

Subsequently, a first patterning process for the first display element DE1 and the first sealing layer SE1 is performed (process P7 in FIG. 5). In the first patterning process, first, as shown in FIG. 15, of the first sealing layer SE1, the portion exposed from the first resist R1 is removed by dry etching (process P21 in FIG. 6).

For this dry etching, an etching gas containing fluorine is used. For the etching gas, for example, sulfur hexafluoride (SF₆), tetrafluoromethane (CF₄), hexafluoroethane (C₂F₆), trifluoromethane (CHF₃) or nitrogen trifluoride (NF₃) may be used. For example, the second layer L2 of the first cap layer CP1 functions as an etching stopper of the dry etching.

Through the dry etching, the surface layer of the first resist R1 could be cured. For this reason, the surface layer of the first resist R1 is cut by ashing (process P22 in FIG. 6). By this process, the first resist R1 can be easily removed in subsequent processes.

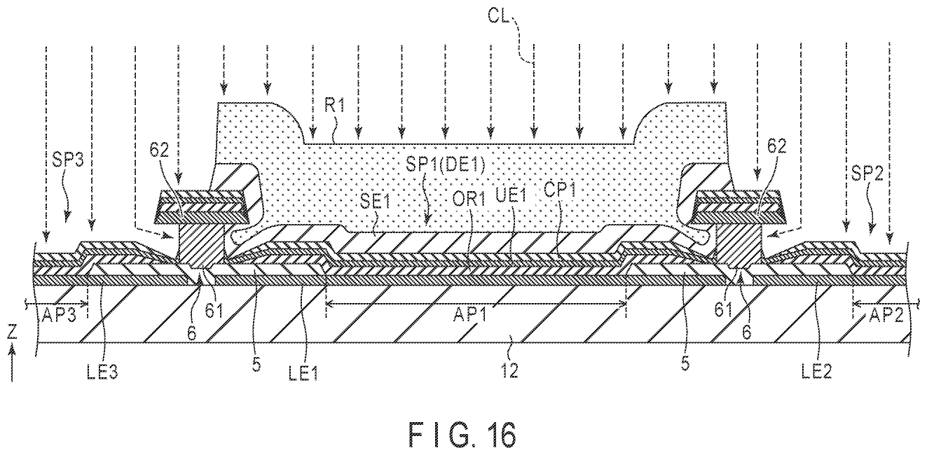

Subsequently, as shown in FIG. 16, the substrate in which the first display element DE1 is formed is washed (process P23 in FIG. 6). In this process, the substrate is provided in a chamber for washing, and is exposed to a cleaning liquid CL injected from a shower device for a certain period of time. The certain period of time is, for example, less than or equal to 10 minutes, and is, for example, 5 minutes.

The cleaning liquid CL is, for example, pure water. However, the cleaning liquid CL is not limited to this example. For the cleaning liquid CL, another liquid containing water such as aqueous sodium hydroxide, aqueous potassium hydroxide, phosphoric acid aqueous solution, hydrofluoric acid aqueous solution, oxalic acid aqueous solution, nitric acid aqueous solution and acetic acid aqueous solution may be used.

Immediately after the dry etching for the first sealing layer SE1 described above, the components of the etching gas such as fluorine could be attached to portions including the side surfaces of the lower portions 61 adjacent to the second subpixel SP2 and the third subpixel SP3. By washing using the cleaning liquid CL, the components of the etching gas are removed from the side surfaces of the lower portions 61, etc.

After the washing, the substrate is dried by, for example, air drying. After the drying, in the present embodiment, the first resist R1 is removed by an exfoliation liquid (process P24 in FIG. 6).

After the first resist R1 is removed, of the second layer L2 of the first cap layer CP1, the portion exposed from the first sealing layer SE1 is removed by wet etching (process P25 in FIG. 6). Further, of the first layer L1 of the first cap layer CP1, the portion exposed from the first layer SE1 is removed by ashing (process P26 in FIG. 6).

Subsequently, of the first upper electrode UE1, the portion exposed from the first sealing layer SE1 is removed by wet etching (process P27 in FIG. 6). Further, of the first organic layer OR1, the portion exposed from the first sealing layer SE1 is removed by ashing (process P28 in FIG. 6). Lastly, the residue of each layer is removed by washing with an exfoliation liquid or ashing (process P29 in FIG. 6).

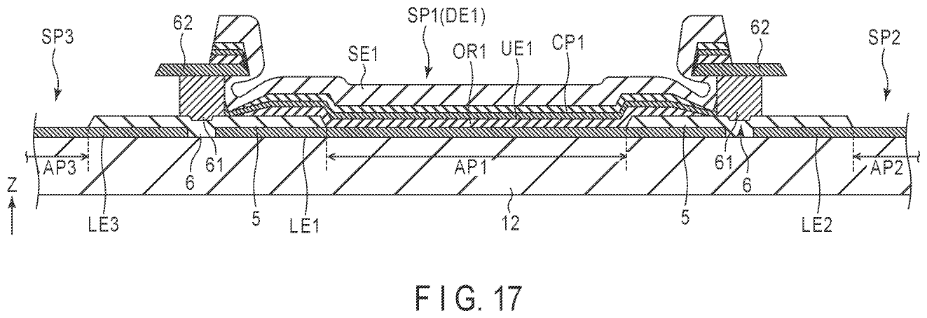

The first patterning process described above allows the acquisition of the following substrate. As shown in FIG. 17, in the substrate, the first display element DE1 and the first sealing layer SE1 are formed in the first subpixel SP1, and neither a display element nor a sealing layer is formed in the second subpixel SP2 or the third subpixel SP3.

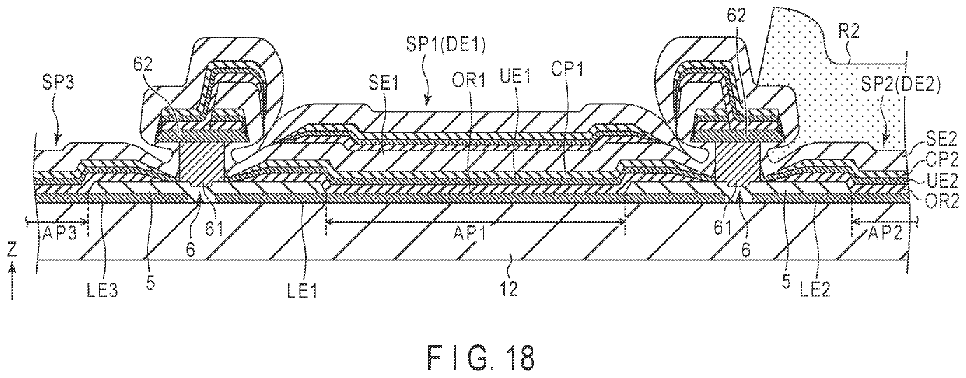

After the first patterning process, the second display element DE2 and the second sealing layer SE2 are formed (process P8 in FIG. 5). Specifically, as shown in FIG. 18, the second organic layer OR2 which is in contact with the second lower electrode LE2 through the second pixel aperture AP2, the second upper electrode UE2 which covers the second organic layer OR2, the second cap layer CP2 which covers the second upper electrode UE2 and the second sealing layer SE2 which covers the second cap layer CP2 are formed in order. These second organic layer OR2, second upper electrode UE2, second cap layer CP2 and second sealing layer SE2 are formed in at least the entire display area DA and are provided in the first subpixel SP1 and the third subpixel SP3 as well as the second subpixel SP2.

After process P8, as shown in FIG. 18, a second resist R2 is formed on the second sealing layer SE2 (process P9 in FIG. 5). The second resist R2 covers the second subpixel SP2 and part of the partition 6 around the second subpixel SP2.

Subsequently, a second patterning process for the second display element DE2 and the second sealing layer SE2 is performed (process P10 in FIG. 5). The flow of the second patterning process is similar to that of the first patterning process.

In other words, of the second sealing layer SE2, the portion exposed from the second resist R2 is removed by dry etching (process P21 in FIG. 6). The surface layer of the second resist R2 is cut by ashing (process P22 in FIG. 6). Subsequently, the substrate is washed by a cleaning liquid CL (process P23 in FIG. 6). After the substrate is dried, the second resist R2 is removed (process P24 in FIG. 6).

Subsequently, of the second cap layer CP2 (the first layer L1 and the second layer L2), the second upper electrode UE2 and the second organic layer OR2, the portions exposed from the second sealing layer SE2 are removed in series (processes P25 to P28 in FIG. 6), and further, the residue of each layer is removed (process P29 in FIG. 6).

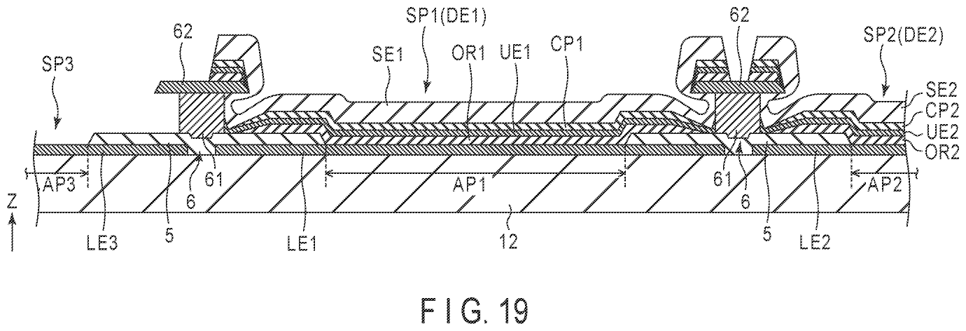

The second patterning process described above allows the acquisition of the following substrate. As shown in FIG. 19, in the substrate, the first display element DE1 and the first sealing layer SE1 are formed in the first subpixel SP1, and the second display element DE2 and the second sealing layer SE2 are formed in the second subpixel SP2, and neither a display element nor a sealing layer is formed in the third subpixel SP3.

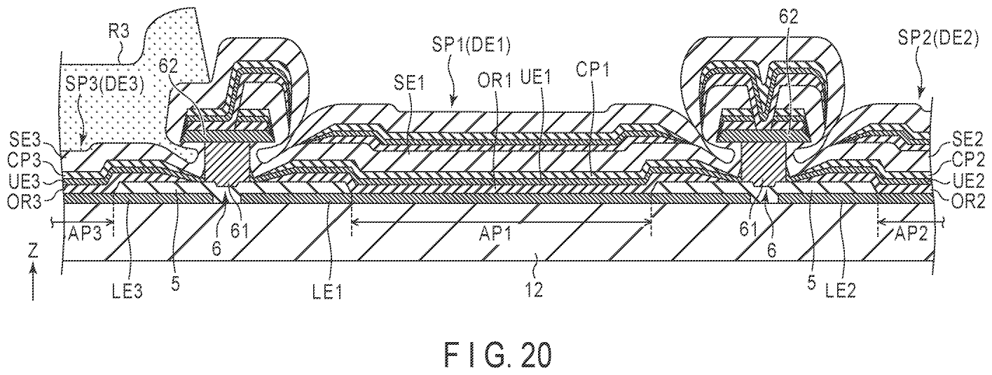

After the second patterning process, the third display element DE3 and the third sealing layer SE3 are formed (process P11 in FIG. 5). Specifically, as shown in FIG. 20, the third organic layer OR3 which is in contact with the third lower electrode LE3 through the third pixel aperture AP3, the third upper electrode UE3 which covers the third organic layer OR3, the third cap layer CP3 which covers the third upper electrode UE3 and the third sealing layer SE3 which covers the third cap layer CP3 are formed in order. These third organic layer OR3, third upper electrode UE3, third cap layer CP3 and third sealing layer SE3 are formed in at least the entire display area DA and are provided in the first subpixel SP1 and the second subpixel SP2 as well as the third subpixel SP3.

After process P11, as shown in FIG. 20, a third resist R3 is formed on the third sealing layer SE3 (process P12 in FIG. 5). The third resist R3 covers the third subpixel SP3 and part of the partition 6 around the third subpixel SP3.

Subsequently, a third patterning process for the third display element DE3 and the third sealing layer SE3 is performed (process P13 in FIG. 5). The flow of the third patterning process is similar to the flows of the first patterning process and the second patterning process.

In other words, of the third sealing layer SE3, the portion exposed from the third resist R3 is removed by dry etching (process P21 in FIG. 6). The surface layer of the third resist R3 is cut by ashing (process P22 in FIG. 6). Subsequently, the substrate is washed by a cleaning liquid CL (process P23 in FIG. 6). After the substrate is dried, the third resist R3 is removed (process P24 in FIG. 6).

Subsequently, of the third cap layer CP3 (the first layer L1 and the second layer L2), the third upper electrode UE3 and the third organic layer OR3, the portions exposed from the third sealing layer SE3 are removed in series (processes P25 to P28 in FIG. 6), and further, the residue of each layer is removed (process P29 in FIG. 6).

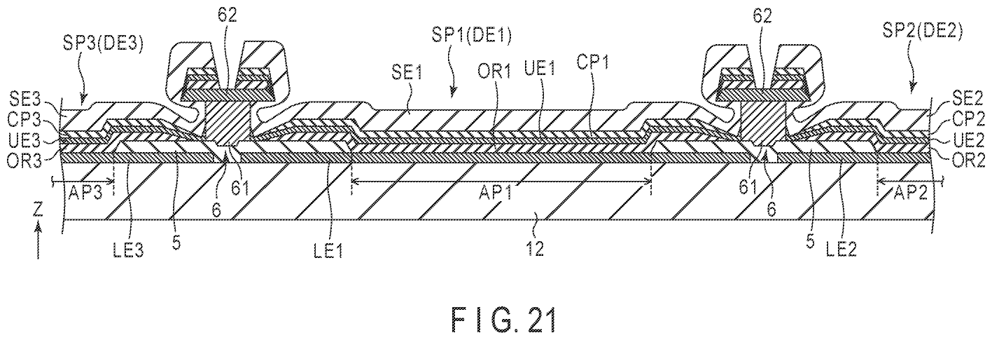

The third patterning process described above allows the acquisition of the following substrate. As shown in FIG. 21, in the substrate, the first display element DE1 and the first sealing layer SE1 are formed in the first subpixel SP1, and the second display element DE2 and the second sealing layer SE2 are formed in the second subpixel SP2, and the third display element DE3 and the third sealing layer SE3 are formed in the third subpixel SP3.

After the display elements DE1, DE2 and DE3 and the sealing layers SE1, SE2 and SE3 are formed in the above matter, the resinous layer 13, sealing layer 14 and resinous layer 15 shown in FIG. 3 are formed in order. Thus, the display device DSP is completed (process P14 in FIG. 5).

In the manufacturing method of the present embodiment described above, if the substrate is not washed in process P23, there is a possibility that an undesired layer is formed on a side surface of the lower portion 61 of the partition 6 because of the etching gas used in the dry etching for the sealing layers SE1, SE2 and SE3. For example, when the lower portion 61 contains aluminum, and the etching gas contains fluorine, this layer could be formed of aluminum fluoride (AlF₃).

For example, when such an undesired layer is formed in the first patterning process, this layer intervenes between the upper electrodes UE2 and UE3 which are formed later and the side surfaces of the lower portions 61 and may interrupt the conduction between the upper electrodes UE2, UE3 and the lower portions 61. Similarly, when such a layer is formed in the second patterning process, the conduction between the third upper electrode UE3 which is formed later and the side surface of the lower portion 61 could be interrupted.

In the present embodiment, the side surfaces of the lower portion 61 are washed by the cleaning liquid CL. In this way, the components of the etching gas attached to the side surfaces of the lower portion 61, etc., are removed, thereby preventing the formation of the undesired layer described above. As a result, the conduction between the upper electrodes UE2 and UE3 and the lower portions 61 is satisfactorily assured. Thus, the reliability of the display device DSP can be enhanced.

In the present embodiment, after the dry etching for the sealing layers SE1, SE2 and SE3, washing is performed using the cleaning liquid CL before etching for the upper electrodes UE1, UE2 and UE3, specifically, before the etching of the cap layers CP1, CP2 and CP3. Thus, the components of the etching gas can be satisfactorily removed by performing washing with the cleaning liquid CL immediately after the dry etching for the sealing layers SE1, SE2 and SE3.

As the display elements DE1, DE2 and DE3 have a low resistance to moisture, in general, the substrate is not washed by a cleaning liquid containing water after the formation of the display elements DE1, DE2 and DE3. Even when the substrate is washed, the substrate needs to be sufficiently dried by, for example, heating. In this regard, in the present embodiment, the display elements DE1, DE2 and DE3 are divided by the partitions 6 having an overhang shape. Further, the display elements DE1, DE2 and DE3 are covered with the sealing layers SE1, SE2 and SE3 including the end portions of the display elements DE1, DE2 and D3. By this configuration, even when the substrate is washed using the cleaning liquid CL, the impregnation of moisture into the display elements DE1, DE2 and DE3 is prevented. Thus, the manufacturing process can be simplified by, for example, applying air drying to dry the substrate.

It should be noted that the manufacturing method of the display device DSP disclosed in the present embodiment could be modified in various ways. Some modified examples are disclosed below.

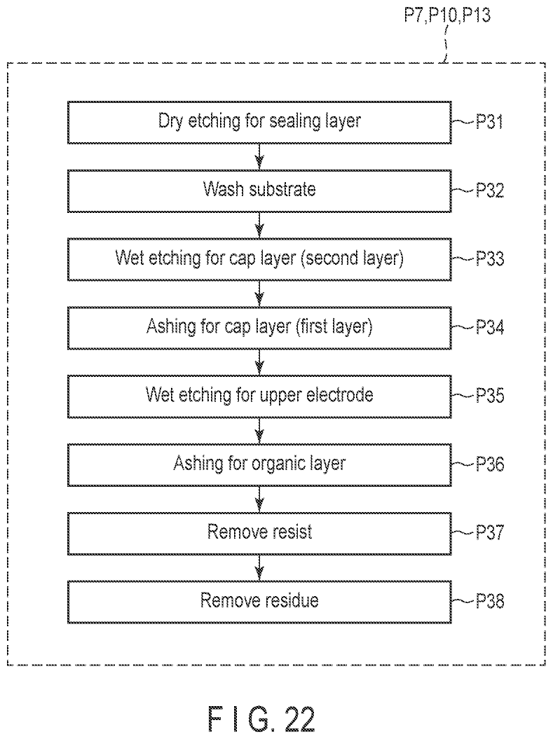

FIG. 22 is a flowchart showing a patterning process (processes P7, P10 and P13 in FIG. 5) according to a first modified example. When the first modified example is applied to the first patterning process, in a manner similar to that of process P21 in FIG. 5, first, of the first sealing layer SE1, the portion exposed from the first resist R1 is removed by dry etching (process P31 in FIG. 22). Immediately after this dry etching, in a manner similar to that of process P23 in FIG. 5, the substrate is washed by the cleaning liquid CL (process P32 in FIG. 22).

Subsequently, without removing the first resist R1, in a manner similar to that of processes P25 to P28 in FIG. 5, of the first cap layer CP1, the first upper electrode UE1 and the first organic layer OR1, the portions exposed from the first sealing layer SE1 (the portions exposed from the first resist R1) are removed in series (processes P33 to P36 in FIG. 22). Subsequently, the first resist R1 is removed by an exfoliation liquid (process P37 in FIG. 22). Further, the residue of each layer is removed (process P38 in FIG. 22). To the second patterning process and the third patterning process, a flow similar to that of the first patterning process can be applied.

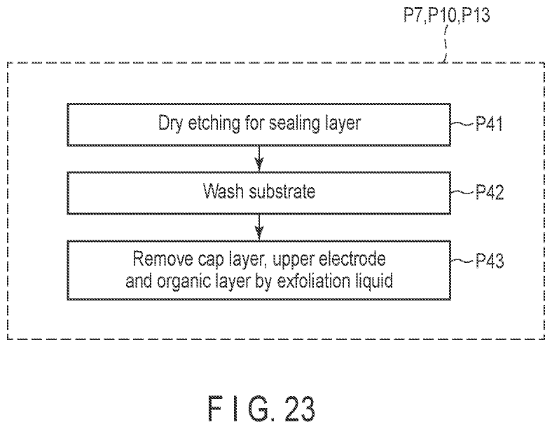

FIG. 23 is a flowchart showing a patterning process (processes P7, P10 and P13 in FIG. 5) according to a second modified example. When the second modified example is applied to the first patterning process, in a manner similar to that of process P21 in FIG. 5, first, of the first sealing layer SE1, the portion exposed from the first resist R1 is removed by dry etching (process P41 in FIG. 23). Immediately after this dry etching, in a manner similar to that of process P23 in FIG. 5, the substrate is washed by the cleaning liquid CL (process P42 in FIG. 23).

Subsequently, of the first cap layer CP1, the first upper electrode UE1 and the first organic layer OR1, the portions exposed from the first sealing layer SE1 are simultaneously removed by an exfoliation liquid (process P43 in FIG. 23). The first resist R1 may be removed in process P43 together or may be removed in another process which is performed before or after process P43. To the second patterning process and the third patterning process, a flow similar to that of the first patterning process can be applied.

Even when the patterning processes of the first modified example and the second modified example are applied, effects similar to those of the present embodiment described above can be obtained.

All of the manufacturing methods that can be implemented by a person of ordinary skill in the art through arbitrary design changes to the manufacturing method of the display device described above as the embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiment by adding or deleting a structural element or changing the design of a structural element, or adding or omitting a step or changing the condition of a step, all of the modifications fall within the scope of the present invention as long as they are in keeping with the spirit of the invention.

Further, other effects which may be obtained from each embodiment and are self-explanatory from the descriptions of the specification or can be arbitrarily conceived by a person of ordinary skill in the art are considered as the effects of the present invention as a matter of course.

What is claimed is:

1. A manufacturing method of a display device, comprising:
forming a first display element on a substrate, the first display element including a first lower electrode, a first upper electrode and a first organic layer located between the first lower electrode and the first upper electrode;
forming a first sealing layer which covers the first display element;
forming a first resist on the first sealing layer; and
removing, of the first sealing layer and the first display element, a portion exposed from the first resist by a first patterning process including washing of the substrate with a cleaning liquid containing water.

2. The manufacturing method of claim 1, wherein
the cleaning liquid is pure water.

3. The manufacturing method of claim 1, wherein
the first patterning process includes:
removing, of the first sealing layer, a portion exposed from the first resist by dry etching; and
washing the substrate using the cleaning liquid after the dry etching.

4. The manufacturing method of claim 3, wherein
the first patterning process further includes removing, of the first upper electrode, a portion exposed from the first sealing layer after the dry etching by etching, and
after the dry etching for the first sealing layer, the washing with the cleaning liquid is performed before the etching for the first upper electrode.

5. The manufacturing method of claim 3, wherein
the first display element further includes a first cap layer which is provided between the first upper electrode and the first sealing layer and which adjusts an optical property of the first display element,
the first patterning process further includes removing, of the first cap layer, a portion exposed from the first sealing layer after the dry etching by etching, and
after the dry etching for the first sealing layer, the washing with the cleaning liquid is performed before the etching for the first cap layer.

6. The manufacturing method of claim 3, further comprising:
forming a partition on the substrate before forming the first display element, the partition including a conductive lower portion and an upper portion which protrudes from a side surface of the lower portion.

7. The manufacturing method of claim 6, wherein
a part of the side surface of the lower portion is washed by the cleaning liquid.

8. The manufacturing method of claim 6, wherein
an etching gas containing fluorine is used for the dry etching for the first sealing layer, and
the lower portion contains aluminum.

9. The manufacturing method of claim 1, further comprising:
forming a second display element on the substrate after the first patterning process, the second display element including a second lower electrode, a second upper electrode and a second organic layer located between the second lower electrode and the second upper electrode;
forming a second sealing layer which covers the second display element;
forming a second resist on the second sealing layer; and
removing, of the second sealing layer and the second display element, a portion exposed from the second resist by a second patterning process including washing of the substrate with the cleaning liquid.

10. The manufacturing method of claim 9, further comprising:
forming a third display element on the substrate after the second patterning process, the third display element including a third lower electrode, a third upper electrode and a third organic layer located between the third lower electrode and the third upper electrode;
forming a third sealing layer which covers the third display element;
forming a third resist on the third sealing layer; and
removing, of the third sealing layer and the third display element, a portion exposed from the third resist by a third patterning process including washing of the substrate with the cleaning liquid.
